(19) United States
(12) Patent Application Publication
(10) Pub. No.: US 2007/0210311 A1
(43) Pub. Date: Sep. 13, 2007

(54) THIN FILM TRANSISTOR SUBSTRATE AND PROCESS FOR PRODUCING SAME

(76) Inventors: Masahiko Ando, Hitachinaka (JP); Tomohiro Inoue, Tsukuba (JP); Tadashi Arai, Kumagaya (JP); Masaaki Fujimori, Hatoyama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/624,801

(22) Filed: Jan. 19, 2007

(30) Foreign Application Priority Data
Mar. 13, 2006 (JP) 2006-066880

(51) Int. Cl. H01L 29/04

(52) U.S. Cl. 257/59

(57) ABSTRACT

In conventional techniques, there has been a problem such that a pattern failure tends to occur in which electrode patterns formed by coating do not coincide with lyophilic patterns and the coating process is complicated to degrade the productivity. The present invention provides a thin film transistor substrate including: a substrate; a plurality of gate electrodes formed on a flat surface of the substrate so as to form an array constituted with ring-shaped flat patterns formed by continuously connecting the outer peripheries of a plurality of ellipses aligned along the major axis direction, or patterns each formed with the peripheral shape of an ellipse; a gate insulating film formed over the gate electrodes; and source electrodes and drain electrodes formed on the gate insulating film exclusive of the flat surface regions, on the gate insulating film, defined as the projected shapes of the gate electrodes.

### BACKGROUND OF THE INVENTION

(1) Field of the Invention

The present invention relates to a thin film transistor substrate including a plurality of thin film transistors (TFTs) and a process for producing the thin film transistor substrate.

(2) Description of Related Art

In flat panel display devices using liquid crystals and organic EL (Electro Luminescence) elements, thin film transistors (hereinafter abbreviated as TFTs) using amorphous silicon and polycrystalline silicon for transistor films and using aluminum, chromium and the like for electrodes are used as pixel driving elements. These transistor films and electrodes are formed by photolithography pattern processing of thin films formed by means of vacuum device techniques such as the plasma-enhanced chemical vapor deposition method and sputtering. On the other hand, for the purpose of reducing the production cost, improving the productivity, and actualizing display devices having plasticity and the like purposes, recently there have been actively developed the techniques for forming semiconductor films and electrode films by means of coating by printing with organic molecule dispersion solutions and conductive ink materials in which metal nanoparticles or conductive polymers are dispersed in solvents, and by using non-vacuum devices typified by inkjet and the like.

In general, the conventional photolithography method is approximately 1 μm in the positioning accuracy of each of the patterns of semiconductor films, gate electrodes, drain electrodes and source electrodes, and hence can form relatively fine TFTs in arrays with high dimensional accuracy. On the other hand, the coating-by-printing method is a few tens μm or larger in the positioning accuracy of each of the patterns, and hence cannot form fine TFTs and suffers a problem that variation is large. It may be noted that in a TFT used in a flat panel display device, a gate electrode is connected to the scanning wiring and a drain electrode is connected to the signal wiring; a set of the gate electrode and the scanning line and a set of the drain electrode and the signal line are each integrated into one piece and there is no definite boundary between the members in each set, and hence hereinafter, these sets will be simply referred to as the gate electrode and the drain electrode, respectively.

In this connection, WO2005/024956A1 discloses a TFT substrate and a process for producing the TFT substrate, the TFT substrate being formed as follows: lyophobic regions having nearly the same shapes as gate electrodes are formed on a gate insulating film by irradiation of light (exposure) from the backside of a substrate using as a photomask the gate electrodes each having a rectangular opening formed by combining straight-line patterns; and drain electrodes and source electrodes are formed so as to be in self-alignment in relation to the gate electrodes by applying a conductive ink to the lyophilic regions that are reverse in shape in relation to the lyophobic regions.

### BRIEF SUMMARY OF THE INVENTION

An object of the present invention is to provide, on the basis of the TFT and the process for producing the TFT described in WO2005/024956A1, a thin film transistor substrate capable of being formed by coating with suppressed pattern failure and with stationarily high productivity, and a process for producing the thin film transistor substrate.

For the purpose of achieving the above-mentioned object, in the present invention, the thin film transistor substrate includes: a plurality of gate electrodes formed and aligned on a flat surface of the substrate to be constituted with ring-shaped flat patterns having openings; a gate insulating film formed over the gate electrodes; and source electrodes and drain electrodes formed on the gate insulating film exclusive of flat surface regions, on the gate insulating film, defined as projected shapes of the gate electrodes; wherein the ring-shaped flat patterns of the gate electrodes are patterns formed by continuously connecting the outer peripheries of a plurality of ellipses aligned along a major axis direction, or patterns each formed with an outer-periphery shape of an ellipse.

Further, the thin film transistor substrate includes: a semiconductor film formed in the flat surface regions, on the gate insulating film, defined as the projected shapes of the gate electrodes; a passivation insulating film formed over the semiconductor film, the source electrodes and the drain electrodes; and pixel electrodes formed on the passivation insulating film and connected to the source electrodes through the intermediary of through holes.

Further, a process for producing a thin film transistor substrate includes: forming and aligning on the substrate a plurality of the gate electrodes to be constituted with ring-shaped flat patterns wherein the ring-shaped flat patterns of the gate electrodes are patterns formed by continuously connecting the outer peripheries of a plurality of ellipses aligned along the major axis direction, or patterns each formed with the outer-periphery shape of an ellipse; forming a gate insulating film over the plurality of the gate electrodes formed in an array; forming a photosensitive lyophobic monolayer on the gate insulating film; forming lyophilic regions by irradiating the substrate with light from the side opposite to the side on which the gate electrodes are arranged, and removing the lyophobic monolayer formed in the regions which are not light shielded by the gate electrodes; and producing the source electrodes and the drain electrodes by applying a conductive ink on the lyophilic regions and by firing the applied conductive ink.

Further, the process for producing a thin film transistor substrate includes: partially removing the lyophobic monolayer formed between the source electrodes and the drain electrodes; forming the semiconductor film by applying a semiconductor coating liquid to the regions from which the lyophobic monolayer has been removed; forming a passivation insulating film over the source electrodes, the drain electrodes and the semiconductor film; forming the through holes by partially removing the passivation insulating film from above the source electrodes; and forming the pixel electrodes on the passivation insulating film so as to be connected to the source electrodes through the intermediary of the through holes.

The present invention provides a thin film transistor substrate capable of being formed by coating with suppressed pattern failure and stationarily high productivity, and a process for producing the thin film transistor substrate.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWING

FIG. 1 is a view showing an example of the flat patterns of gate electrodes of a thin film transistor substrate according to the present invention;

FIG. 2A1 is a view showing a plane in a production step of a thin film transistor substrate according to the present invention;

FIG. 2A2 is a view showing the A-A section in FIG. 2A1;

FIG. 2B1 is a view showing a plane in a production step of a thin film transistor substrate according to the present invention;

FIG. 2B2 is a view showing the A-A section in FIG. 2B1;

FIG. 2C1 is a view showing a plane in a production step of a thin film transistor substrate according to the present invention;

FIG. 2C2 is a view showing the A-A section in FIG. 2C1;

FIG. 2D1 is a view showing a plane in a production step of a thin film transistor substrate according to the present invention;

FIG. 2D2 is a view showing the A-A section in FIG. 2D1;

FIG. 2E1 is a view showing a plane in a production step of a thin film transistor substrate according to the present invention;

FIG. 2E2 is a view showing the A-A section in FIG. 2E1;

FIG. 2F1 is a view showing a plane in a production step of a thin film transistor substrate according to the present invention;

FIG. 2F2 is a view showing the A-A section in FIG. 2F1;

FIG. 3A is a diagram showing an illustrative example of the procedures for forming the gate electrode flat patterns of the present invention;

FIG. 3B is a diagram showing an illustrative example of the procedures for forming the gate electrode flat patterns of the present invention;

FIG. 3C is a diagram showing an illustrative example of the procedures for forming the gate electrode flat patterns of the present invention;

FIG. 4A is a view showing an example of a process for coating the source electrodes and the drain electrodes of the present invention;

FIG. 4B is a view showing another example of the process for coating the source electrodes and the drain electrodes of the present invention; and

FIG. 5 is a view showing an example of an active matrix display device using the thin film transistor substrate of the present invention.

### DESCRIPTION OF REFERENCE NUMERALS

21 . . . Source electrode coating region, 22 . . . Drain electrode coating region, 23 . . . Junction, 24 . . . Gate electrode constituent unit, 30 . . . Elliptic ring, 31 . . . Prototype of gate electrode constituent unit, 32 . . . Drain electrode region, 33 . . . Source electrode region, 34 . . . Interspace, 41 . . . Drain electrode coating liquid, 42 . . . Source electrode coating liquid, 43 . . . Drain and source electrode coating liquid, 51 . . . Pixel unit, 52 . . . Pixel switching TFT, 53 . . . Scanning line, 54 . . . Signal line, 55 . . . Pixel capacity, 56 . . . Scanning line driving circuit, 57 . . . Signal line driving circuit, 101 . . . Substrate, 102 . . . Gate electrode, 103 . . . Gate insulating film, 104, 108 . . . Lyophobic monolayer, 105 . . . Drain electrode, 106 . . . Source electrode, 107 . . . Gate insulating film surface, 109 . . . Semiconductor coating liquid, 110 . . . Semiconductor film, 111 . . . Passivation insulating film, 112 . . . Through-hole, 113 . . . Pixel electrode

### DETAILED DESCRIPTION OF THE INVENTION

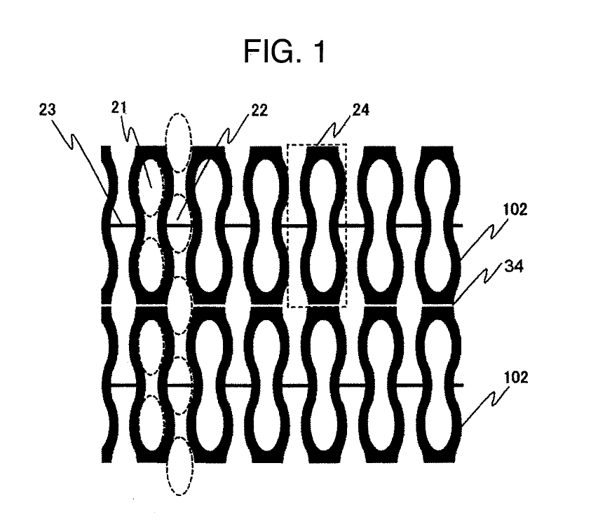

FIG. 1 is a view showing an example of the structure of the flat patterns of the gate electrodes of a thin film transistor substrate of the present invention.

Reference numeral 102 denotes a flat pattern of the gate electrode of the present invention, 21 denotes a source electrode coating region to be described later, 22 denotes a drain electrode coating region to be described later, 23 denotes a junction. Reference numeral 24 denotes a gate electrode constituent unit of the present invention; and the present Example shows a 2×6 TFT matrix in which six gate electrode constituent units are connected in a transverse direction with the junctions 23, and two gate electrode constituent units are closely disposed in a longitudinal direction through the intermediary of an interspace 34.

The gate electrode 102 of the present invention is constituted with a ring-shaped flat pattern having an opening in which pattern two ellipses each represented with a dotted line are smoothly connected along the major axis direction, namely, a flat pattern formed by continuously connecting outer peripheries (contours) of a plurality of ellipses aligned along the major axis direction, and the pattern may be a flat pattern formed with the circumference (contour) of an ellipse. These ring-shaped flat patterns of the gate electrodes are disposed in a transverse direction with even intervals to form a shape in which the ring-shaped patterns are connected to each other with the junctions 23. The shape is characterized in that the opening in any one of the gate electrode flat patterns has a certain curvature and has a shape involving no angular portion; further, the shape and volume of the opening are approximately the same as those of each of the regions between the gate electrode patterns.

These gate electrodes 102 are closely disposed along the longitudinal direction through the intermediary of the interspaces 34, and consequently, the regions formed by longitudinally connecting the voids between the ring-shaped patterns form the shapes in which a plurality of the ellipses having approximately the same shapes as the ellipses forming the openings of the ring-shaped patterns are smoothly connected along the major axis direction. In the present Example, a source electrode coating region 26 has a shape in which two ellipses are smoothly connected in the major axis direction; however, the number of the ellipses may be either one or three or more. Additionally, in the present Example, a 2×6 matrix structure of the gate electrode constituent units 24 is adopted; however, an optional matrix can be formed by increasing the number of the connected gate electrode constituent units 24 to extend the gate electrode sequence, namely, by increasing the number of the gate electrodes. A detailed process for forming the ring-shaped flat pattern of the gate electrode 102 is described below.

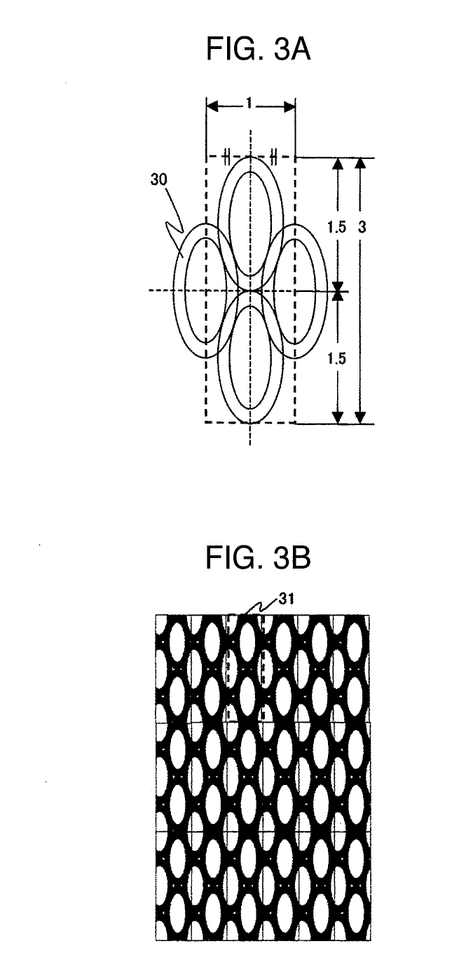

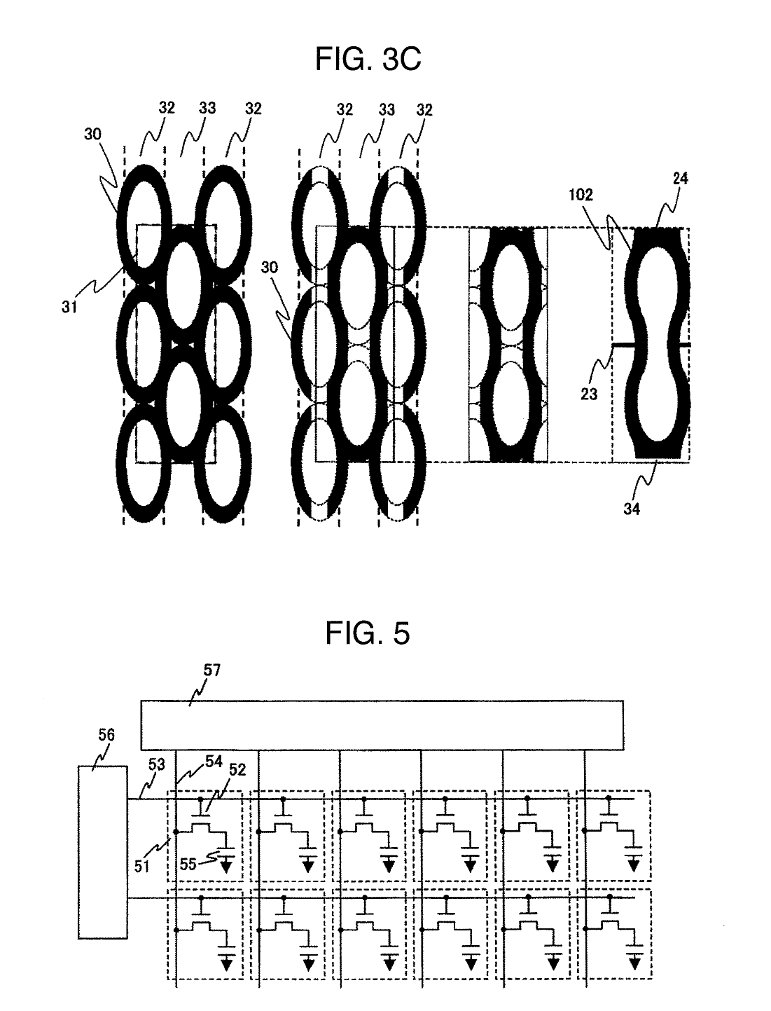

FIGS. 3A to 3C are the views showing the procedures for forming the flat patterns of the gate electrodes on the thin film transistor substrate of the present invention.

The present Example presents a case where the length-to-width ratio of the gate electrode constituent unit 24 is 3:1 and the source electrode coating region 21 is formed with two ellipses. Hereinafter, the short-edge length of the gate electrode constituent unit is defined to be unity. With reference to FIG. 3A, description is made on a procedure for determining the minor axis length of the ellipse in relation to a given rectangular region. In the rectangular region having a long-edge length of 3 and a short-edge length of 1, two elliptical rings 30 are longitudinally disposed to contact each other and so as for the major axes of the elliptical rings to be superposed on the longitudinal centerline of the rectangular region, wherein the outer periphery of each of the elliptical rings 30 is an ellipse having a major axis length of 1.5 and the opening of each of the elliptical rings 30 is a homothetic ellipse, smaller than this ellipse, to form the inner periphery of any one of the elliptical rings 30. Two elliptical rings the same in shape as the above-mentioned elliptical rings are disposed so as to be the same in orientation in such a way that the intersections between the transverse centerline and both long edges of the rectangular region coincide with the centers of the two elliptical rings. The minor axis lengths of the ellipses defining these elliptical rings are determined in such a way that the inner and outer peripheries of the ellipses disposed on the longitudinal centerline of the rectangular region and the outer and inner peripheries of the ellipses disposed on both long edges of the rectangular region are brought into contact with each other, respectively. Accordingly, the minor axis length is varied depending on the ring width.

FIG. 3B is a view showing a periodic arrangement of the elliptical rings 30 thus determined in shape. With reference to FIG. 3A, the interior of the rectangular region is cut out after the disposition of the elliptical rings 30 on the four corners of the rectangular region so as for the centers of the elliptical rings to coincide with the four corners, and the thus cut-out shape of the interior of the rectangular region is defined as the prototype 31 of the gate electrode constituent unit. FIG. 3B shows an array of the prototypes 31 with three and six of the prototypes 31 along the longitudinal and transverse directions, respectively.

FIG. 3C shows the procedures for trimming the prototype 31 of the gate electrode constituent unit into the gate electrode constituent unit 24. The longitudinal sequences of the elliptical rings 30 are alternately assigned to the drain electrode region 32 and the source electrode region 33. There are removed the portions of the elliptical rings in the drain electrode region 32 falling in the range from the longitudinal centerline to the onset of contact with the outer peripheries of the elliptical rings in the source electrode region 33. On the other hand, there are removed only the portions, longitudinally in contact with each other in the rectangular region, of the elliptical rings in the source electrode region 33 falling in the range from the longitudinal centerline to the onset of contact with the outer peripheries of the elliptical rings in the drain electrode region 32. In this way, there are formed a source electrode coating region having a shape formed by smoothly connecting two ellipses along the major axis direction and a drain electrode coating region having a shape formed by smoothly connecting a plurality of ellipses along the major axis direction. The source electrode coating region in which a source electrode is formed corresponds to the opening of the ring-shaped flat pattern of the gate electrode, and the drain electrode coating region in which a drain electrode is formed corresponds to the region between the adjacent gate electrodes.

Further, the junctions 23 are added to the thus obtained pattern and the pattern portion corresponding to the interspace 34 is removed, and thus there is completed the gate electrode constituent unit 24 shown on the extreme right of FIG. 3C.

The width of the elliptical ring 30 constituting the gate electrode is determined in such a way that the ratio of the area occupied by the gate electrode in the rectangular region is 30% or less. For a rectangular region having a long edge length of 300 μm and a short edge length of 100 μm, for example, the width of the elliptical ring is set to be 70 μm or less. This width is derived on the assumption that when the elliptical ring-shaped portion in FIG. 3B is a lyophobic region and the openings in FIG. 3B are lyophilic regions, and a liquid is applied over the whole surface, the liquid is repelled from the lyophobic region and gathers together in the lyophilic regions to form liquid film patterns identical to the lyophilic regions. When the area ratio of the lyophobic region is 30% or more, there is found a tendency that the liquid tends to remain in the lyophobic region.

With reference to the accompanying drawings, description is made on some embodiments of thin film transistor substrates and display devices based on the present invention and having the flat patterns of the gate electrode 102 of FIG. 1 which patterns can be formed as described above.

### DESCRIPTION OF PREFERRED EMBODIMENT

### Example 1

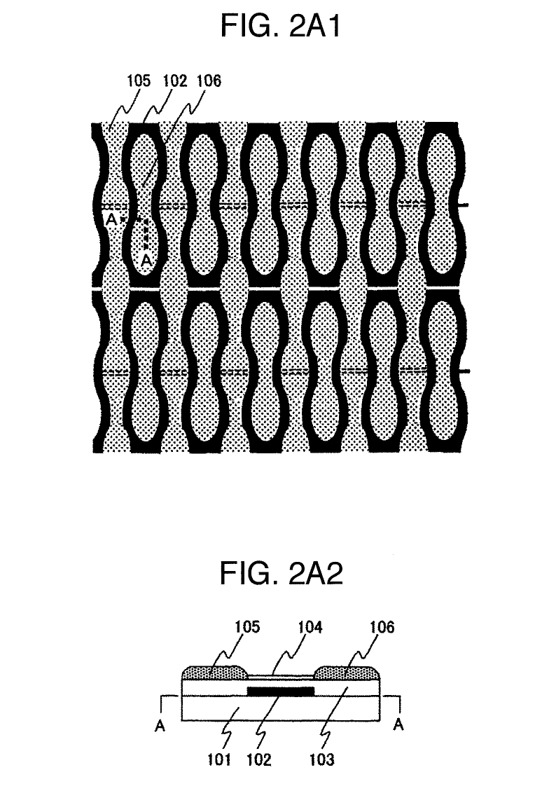

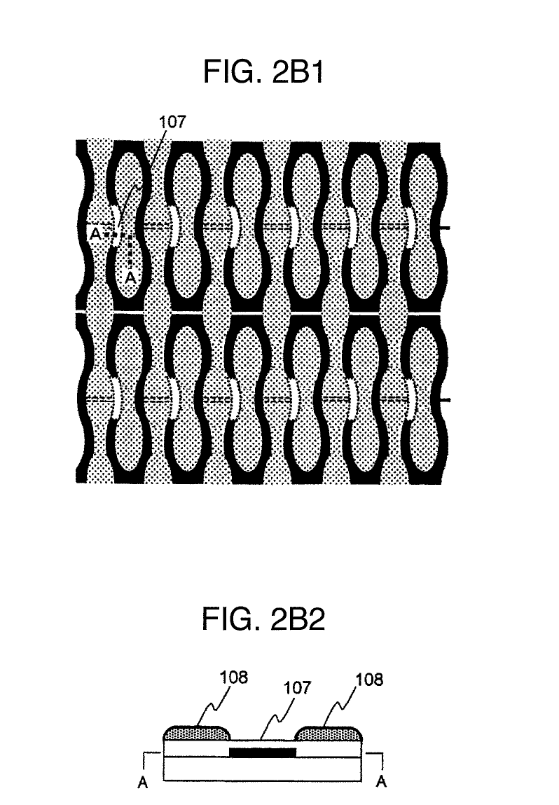

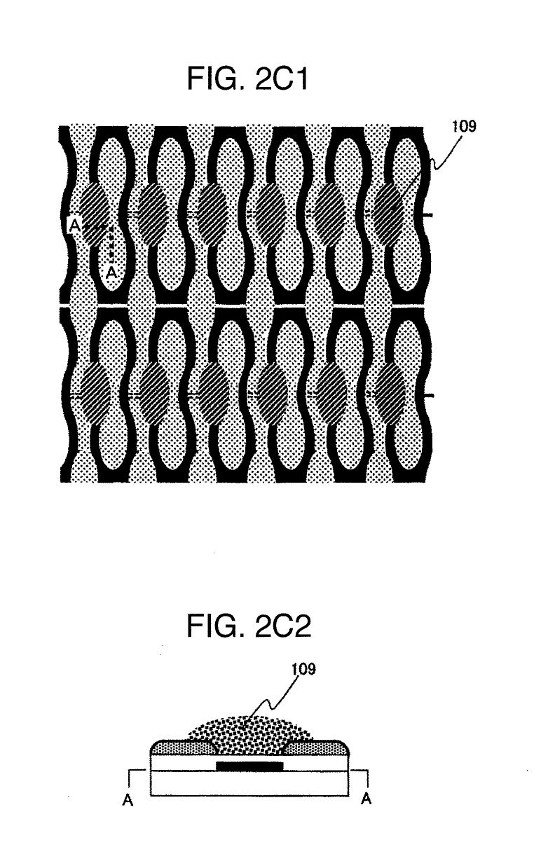

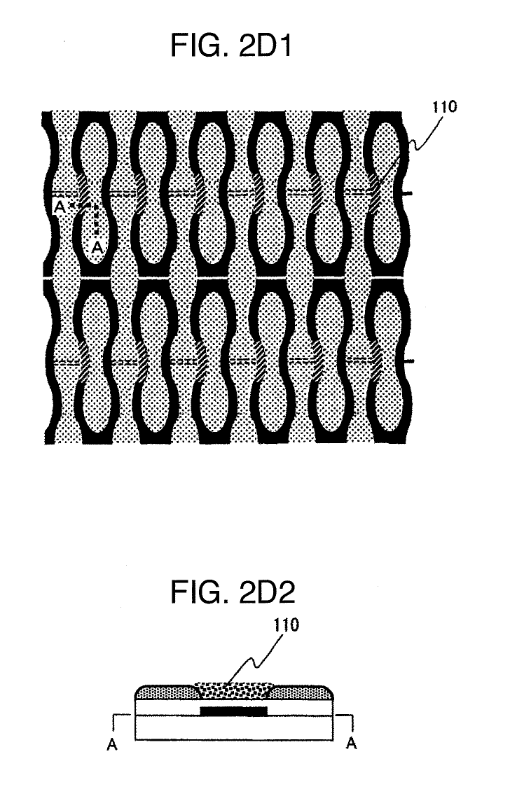

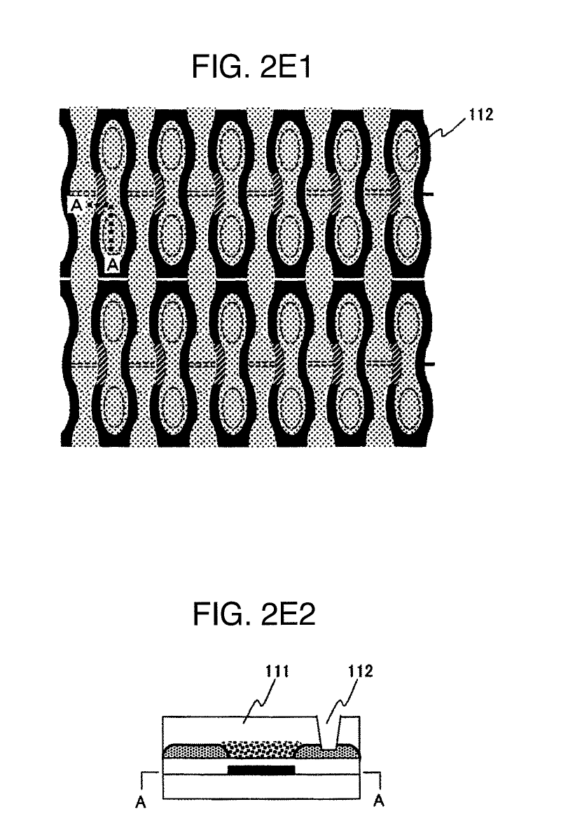

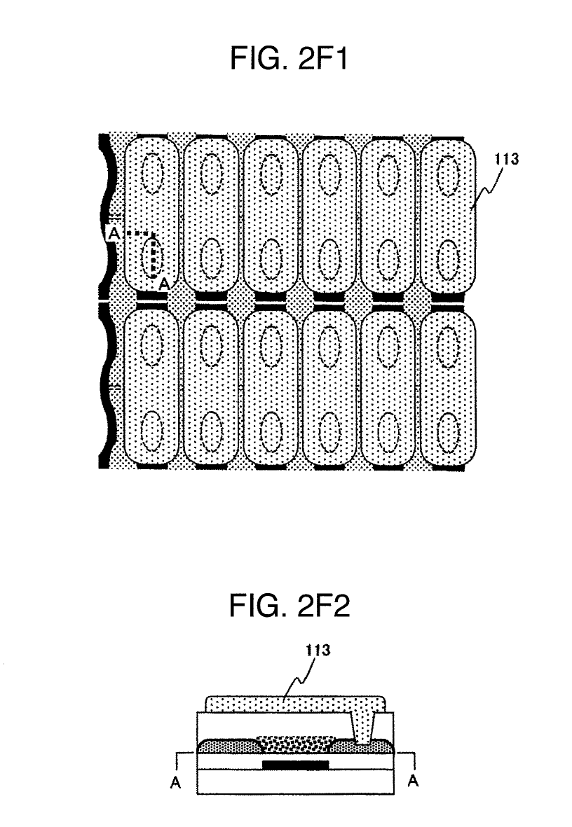

FIGS. 2A1 to 2F2 include plan views each showing a plane in a production step of a thin film transistor substrate according to the present invention and views each showing the A-A section in each of the plan views.

In the present example, the gate electrode unit was set to be 300 μm in length and 100 μm in width, and the elliptical ring width constituting the gate electrode was set to be 10 μm.

First, the drain electrode 105 and the source electrode 106 shown in FIGS. 2A1 and 2A2 as the reverse patterns of the gate electrode 102 were produced as follows. The gate electrode 102 was produced as follows. A 140 nm thick chromium thin film was formed by using a sputtering method on a 0.8 mm thick 1737 glass substrate manufactured by Corning Co. By using an etching solution composed of a mixed solution of ammonium cerium (IV) fluoride and nitric acid and by using a photolithography method, the chromium thin film was processed into patterns shown in the plan view to form the gate electrodes 102. Thereover, a gate insulating film 103 composed of a 300 nm thick silicon oxide film was formed by means of the plasma-enhanced chemical vapor deposition method from a mixed gas raw material composed of tetraethoxysilane and oxygen. Thereover, a negative photoresist to leave the light-exposed portions thereof was spin-coated, and irradiated with light (exposed) from the backside of the substrate (the side opposite to the side of the substrate on which the gate electrodes were disposed), and thus the resist pattern (not shown) as a reverse of the gate electrode pattern was formed. Then, thereover, a fluorinated alkyl silane coupling agent was applied to form a lyophobic monolayer 104.

Specifically, the lyophobic monolayer was formed by the chemical vapor adsorption of 2-perfluorohexylethyltrimethoxysilane [CF₃(CF₂)₅CH₂CH₂Si(OCH₃)₃]. The resist was peeled off with acetone, and the lyophobic monolayer adhered on the resist was also removed (lifted-off) simultaneously. In other words, by removing the lyophobic monolayer formed in the region which was not light shielded by the gate electrodes 102, the lyophobic monolayer 104 having the same patters as the patterns of the gate electrodes 102 was formed. Both on the region in which the lyophobic monolayer 104 was formed and on the region in which the lyophobic monolayer 104 was not formed, there was dropped the conductive ink in an amount enough to coat the region (the source electrode formation region and the drain electrode formation region) in which the lyophobic monolayer 104 was not formed. Thereafter, the dropped conductive ink was fired in an atmosphere of nitrogen gas set at 120° C. to 200° C. for 30 minutes to form the source electrodes 106 and the drain electrodes 105, both being approximately 100 nm in film thickness.

The conductive ink may be an ink which is a liquid containing at least one of a metal nanoparticle, a metal complex or a conductive polymer, the ink having a property being capable of pervading the lyophilic regions of the source and drain electrode portions, and the ink exhibiting sufficiently low resistance after firing. As a specific material, there can be used a solution in which a nanoparticle of approximately 10 nm in diameter or a metal complex, containing as the main components gold, silver, palladium, platinum, copper, nickel and the like is dispersed in a solvent such as water, an alcohol, toluene, xylene, another organic solvent or the like. In Example 1, there was used a silver nanoparticle aqueous dispersion.

The conductive ink is repelled by the lyophobic monolayer 104 adhered to the surface of the gate insulating film above the gate electrode 102, and gathers in the source electrode coating region 21 and the drain electrode coating region 22 shown in FIG. 1; consequently, the source electrodes 106 and the drain electrodes 105 are formed, in a self-aligned manner, as the reverse patterns in relation to the gate electrodes 102. The electrode formation based on the self-alignment means a fact that when a conductive ink is applied both to the lyophobic regions and the lyophilic regions, the lyophobic regions repel the conductive ink and the ink gathers automatically in the lyophilic regions, and consequently, electrodes approximately the same in shape as the lyophilic regions are formed. In other words, the source electrodes 106 and the drain electrodes 105 are automatically formed on the gate insulating film 103 exclusive of the flat region, on the gate insulating film 103, defined as the projected shapes of the gate electrodes 102.

The interspace 34 shown in FIG. 1 is a lyophilic region, but the width of the interspace 34 is as narrow as approximately 5 μm, and hence the conductive ink cannot be stably present therein (nonpervasion effect in WO2005/024956A1), and does not remain therein. Additionally, although the lyophobic monolayer is present on the gate insulating film above the junctions 23 of the gate electrodes 102, the width of the junctions is as narrow as approximately 5 μm, and consequently the conductive ink remains (bridging effect in WO2005/024956A1). Consequently, the drain electrodes 105 are formed to be continuous along the longitudinal direction.

Next, with reference to FIGS. 2B1 to 2D2, description is made on the process for coating formation of the semiconductor film 110 formed in a self-aligned manner. In this case, the drain electrodes and the source electrodes are preferably made of noble metals such as silver and gold. As shown in FIG. 2B-1, the lyophobic monolayer 104 interposed between the drain electrode 105 and the source electrode 106 is partially removed to expose the lyophilic gate insulating film surface 107. Specifically, the lyophobic monolayer is decomposed to be removed by irradiating excimer laser light of 248 nm (KrF) or 193 nm (ArF).

Next, the lyophobic monolayer 108 is formed by the chemical vapor adsorption selectively only over the drain electrode 105 and the source electrode 106. For silver, gold or the like, a thiol monomer having at least one fluoro terminal group is used; specific examples of such a monomer include 4-fluorobenzenethiol and pentafluorobenzenethiol. Herewith, the lyophilic region formed on the gate insulating film surface 107 is surrounded by the lyophobic region due to the lyophobic monolayer remaining on the gate insulating film and the lyophobic region due to the lyophobic monolayer adhered to the source electrode surface and the drain electrode surface. This lyophilic region is approximately 30 μm in length and 10 μm in width. The semiconductor coating liquid is dropped onto this lyophilic region. As the semiconductor coating liquid, a trichlorobenzene solution of pentacene, or a chloroform or toluene solution of poly(3-hexylthiophene) (P3HT), fluorene-bithiophene (F8T2) copolymer or polyphenylenevinylene (PPV) is used. For the dropping method, an inkjet device and a dispenser can be used. In this case, the typical droplet size is approximately 50 μm; as shown in FIGS. 2C1 and 2C2, immediately after the dropping, the droplet overflows from the gate insulating film surface 107 that has been made lyophilic. However, the adjacent semiconductor coating liquids are separated away from each other in such a way that the separation is 100 μm in the transverse direction and 300 μm in the longitudinal direction. Therefore, the liquids are not merged. By setting the substrate temperature approximately at 100° C. to 200° C. when the semiconductor solution is applied, the solvent is evaporated, and as shown in FIGS. 2D1 and 2D2, the semiconductor solution gathers on the lyophilic gate insulating film surface, so that a semiconductor film 110 of approximately 50 nm in film thickness is formed in a self-aligned manner in relation to the drain electrodes and the source electrodes.

As shown in FIGS. 2E1 and 2E2, a passivation insulating film 111 of approximately 2 μm in film thickness is formed over the semiconductor film 110, the source electrode 106 and the drain electrode 105. Thereafter, the passivation insulating film is partially removed from above the source electrode 106 to form a through hole 112. Examples of the usable materials for the passivation insulating film may include polyimide, photosensitive polyimide, polyvinyl alcohol (PVA), photosensitive PVA, polysilazane and polymethylmethacrylate (PMMA). Examples of the usable coating-by-printing machine may include machines involving spin coating, dip coating, screen printing and reverse printing. The firing was carried out at 100° C. to 200° C. for 30 minutes according to the materials. The though hole can be machined with a second harmonic of 355 nm from a YAG laser.

Finally, as shown in FIGS. 2F1 and 2F2, the pixel electrode 113 was formed on the passivation insulating film 111 so as to be connected to the source electrode 106 through the intermediary of the through hole 112. As the material for the pixel electrode 113, a silver nanoparticle dispersion was used; the dispersion was directly printed by means of the screen printing method, and thereafter fired at 100° C. to 200° C. for 30 minutes in an atmosphere of nitrogen.

Such gate electrode flat patterns as described above make the shape and volume of each of the drain electrodes 105 the same as those of each of the source electrodes 106, and consequently make it possible to carry out a simultaneous coating under the same conditions with a multi-head dispenser having a plurality of discharge nozzles disposed with the same pitch as that of the flat patterns; thus, a remarkable improvement effect of the productivity can be attained. Additionally, the drain electrode coating regions 22 and the source electrode coating regions 21 each have a smooth shape with a certain curvature, and hence the conductive ink can reach every corner in each of the regions; consequently, as compared to rectangular regions, there can be attained an advantageous effect capable of suppressing the pattern failure in the source electrodes and the drain electrodes.

### Example 2

In Example 1, the gate electrodes 102 and the gate insulting film 103 were formed on the glass substrate 101 by using a vacuum device and the photolithography method. However, these electrodes and film can also be formed on a plastic substrate by using a non-vacuum device without using the photolithography method. On a 200 μm thick plastic substrate made of PEN (polyethylene naphthalate) or PET (polyethylene terephthalate) with a barrier layer formed of SOG (spin-on glass), a silver nanoparticle dispersion is applied by printing by means of an inkjet method or a screen printing method, and thereafter fired at 200° C. for 30 minutes to form the gate electrodes 102 of 150 nm in film thickness. Thereover, polysilazane dissolved in xylene was applied by means of a spin coating, dip coating or spray coating method, then fired at 300° C. for 1 hour in an atmosphere of oxygen or in a humidified atmosphere to form the gate insulating film 103 made of a silicon oxide film of 300 nm in film thickness. After this stage, by applying the same steps as in Example 1, the TFT substrate can be formed without using a vacuum device and the photolithography method. In this way, the cost of the TFT production apparatus can be drastically reduced and the productivity can also be drastically improved.

Additionally, the flexible plastic substrate is generally larger in thermal expansion and contraction than the glass substrate, and hence the positioning between the respective electrodes and the semiconductor film becomes more difficult. On the contrary, the use of the self-alignment method and the patterns of the present invention makes it possible to carry out accurate positioning even when the coating-by-printing method is applied to the plastic substrate, and hence there is an advantage such that flexible display devices can be provided at low cost.

### Example 3

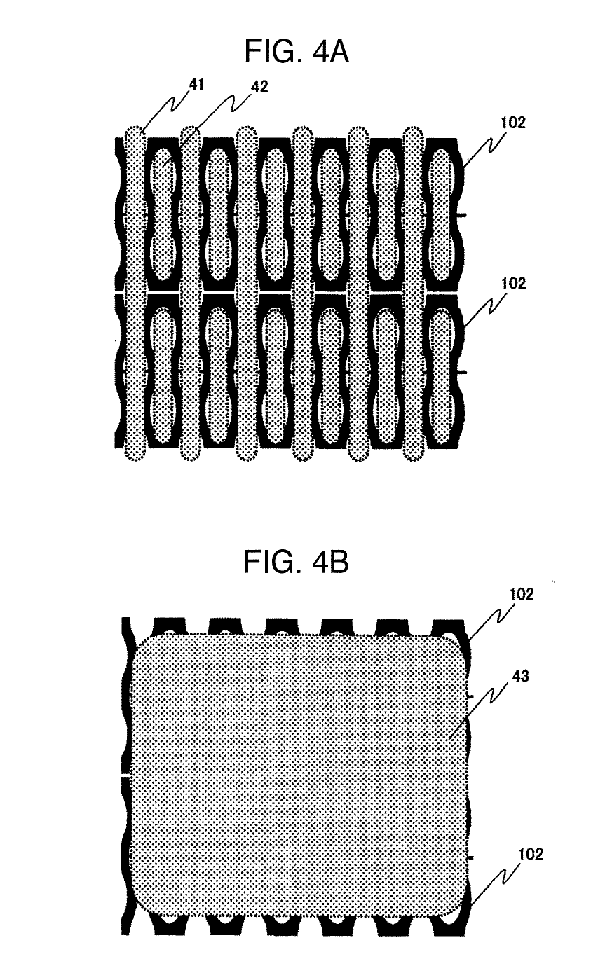

FIGS. 4A and 4B are plan views each showing an example of the process for coating the drain electrodes 105 and the source electrodes 106 in the TFT of the present invention.

FIG. 4A shows the coating liquid patterns immediately after the application of the conductive ink on the drain electrode coating regions 22 and the source electrode coating regions 21 in a straight-line manner by using a dispenser under the same conditions. A drain electrode coating liquid 41 continuously pervades the continuous lyophilic drain electrode coating regions 22. However, a source electrode coating liquid 42 pervades each of the source electrode coating regions 21 without merging these regions although the coating conditions are the same as those for the drain electrode coating liquid 41. This is because the lyophobic regions between the drain electrode coating regions repel the conductive ink discharged from the dispenser even when the conductive ink is brought into contact with the lyophobic region, and hence the conductive ink is not transferred. As described above, in the patterns of the TFT substrate of the present invention, the drain electrodes 105 and the source electrodes 106 are the same in width and pitch, and consequently, it is possible to carry out the simultaneous coating under the same conditions with a multi-head dispenser having a plurality of discharge nozzles disposed with the same pitch as those of the drain and source electrodes; thus, a remarkable improvement effect of the productivity can be attained. Additionally, the drain electrode coating regions 22 and the source electrode coating regions 21 each have a smooth shape with a certain curvature, and hence the conductive ink can reach every corner in each of the regions; consequently, as compared to rectangular regions, there can be attained an advantageous effect capable of suppressing the pattern failure in the source electrodes and the drain electrodes.

The productivity is further improved when a conductive ink as a drain and source electrode coating liquid 43 is applied over the whole surface of the substrate as shown in FIG. 4B. The conductive ink applied over the whole surface by spin coating or spray coating is repelled by the lyophobic monolayer on the gate insulating film and spontaneously disintegrates to gather in the drain electrode coating regions 22 and the source electrode coating regions 21 as shown in FIG. 4A. The advantageous effect of the formation of such spontaneous patterns based on the whole surface coating were obtained when the drain electrode coating regions 22 and the source electrode coating regions 21 were formed with elliptical shapes that make smaller the surface energy of the liquid. However, the selective coating shown in FIG. 4A is higher in the use efficiency of the conductive ink material than the whole substrate surface coating shown in FIG. 4B, and hence has an advantageous effect of reducing the material cost.

### Example 4

FIG. 5 is a view showing an equivalent circuit of an active matrix display device using the TFT substrate composed of 2×6 pixel units each using as the pixel switch the above-mentioned TFT of the present invention.

A scanning line 53 corresponds to the gate electrodes 102 in FIG. 2A1, and a signal line 54 corresponds to the drain electrodes 105 in FIG. 2A1. Six pixel switching TFTs each connected to one of the scanning lines are each set in a conductive state by the scanning signals periodically given through the scanning line 53 from a scanning line driving circuit 56, the signal voltages supplied through the signal line 54 from a signal line driving circuit 57 are given to the pixel capacitors 55, then the pixel switching TFTs are each set in a nonconductive state until the next scanning signal is given thereto and the signal voltages of the individual pixel capacitors are maintained. The so-called linear sequential scanning method in which this operation is repeated sequentially for every scanning line or the active matrix driving method makes it possible to display image information. The construction of a display having a larger number of pixels only requires the increase of the number of the pixel units. The increase of the number of the pixel units corresponds to the increase of the gate electrode constituent unit 24 in FIG. 1.

As shown in FIG. 2F2, the present invention adopts a structure in which the nontransparent gate electrode 102 and source electrode 106 are disposed under the pixel electrode 113, and hence the light transmittance of the pixel unit 51 is low. Accordingly, bright displaying can be attained when there is used a reflection display device such as a reflection liquid crystal or an electrophoretic element which uses the pixel electrode 113 as a reflection electrode, has a display portion disposed between a pair of substrates in the display device to be a pixel capacitor, and displays images by reflecting the external light. Some of these display devices can be formed by printing on flexible substrates. Consequently, the application of the TFT substrate of the present invention enables the provision of flexible and active matrix-driven reflection display devices at low cost.

It should be further understood by those skilled in the art that although the foregoing description has been made on embodiments of the invention, the invention is not limited thereto and various changes and modifications may be made without departing from the spirit of the invention and the scope of the appended claims.

1. A thin film transistor substrate comprising:
a substrate;
a plurality of gate electrodes formed and aligned on a flat surface of the substrate to be constituted with ring-shaped flat patterns having openings;
a gate insulating film formed over the gate electrodes; and
source electrodes and drain electrodes formed on the gate insulating film exclusive of flat surface regions, on the gate insulating film, defined as projected shapes of the gate electrodes;
wherein the ring-shaped flat patterns of the gate electrodes are patterns formed by continuously connecting outer peripheries of a plurality of ellipses aligned along a major axis direction, or patterns each formed with a peripheral shape of an ellipse.

2. The thin film transistor substrate according to claim 1, wherein flat shapes forming the source electrodes and the drain electrodes are approximately the same.

3. The thin film transistor substrate according to claim 1, wherein the openings of the ring-shaped flat patterns of the gate electrodes are regions enclosed with the outer peripheries, and are regions in which the source electrodes are formed.

4. The thin film transistor substrate according to claim 1, wherein regions between the individual gate electrodes are regions in which the drain electrodes are formed.

5. The thin film transistor substrate according to claim 1, wherein the source electrodes and the drain electrodes are arranged on the flat surface of the substrate respectively with approximately even intervals.

6. The thin film transistor substrate according to claim 1, wherein the source electrodes and the drain electrodes are formed as reverse pattern shapes in relation to the gate electrodes.

7. The thin film transistor substrate according to claim 1, wherein a surface of the source electrodes and a surface of the drain electrodes each are formed with a lyophobic monolayer.

8. The thin film transistor substrate according to claim 7, comprising:
a semiconductor film formed in flat surface regions, on the gate insulating film, defined as the projected shapes of the gate electrodes;
a passivation insulating film formed over the semiconductor film, the source electrodes and the drain electrodes; and
pixel electrodes formed on the passivation insulating film and connected to the source electrodes through the intermediary of through holes.

9. A process for producing a thin film transistor substrate, comprising:
forming and aligning on a substrate a plurality of gate electrodes to be constituted with ring-shaped flat patterns wherein the ring-shaped flat patterns of the gate electrodes are patterns formed by continuously connecting the outer peripheries of a plurality of ellipses aligned along the major axis direction, or patterns each formed with the peripheral shape of an ellipse;
forming a gate insulating film over the plurality of the gate electrodes formed in an array;
forming a photosensitive lyophobic monolayer on the gate insulating film;
forming lyophilic regions by irradiating the substrate with light from the side opposite to the side on which the gate electrodes are arranged, and removing the lyophobic monolayer formed in regions which are not light shielded by the gate electrodes; and
producing source electrodes and drain electrodes by applying a conductive ink on the lyophilic regions and by firing the applied conductive ink.

10. The process for producing a thin film transistor substrate according to claim 9, comprising:
partially removing the lyophobic monolayer formed between the source electrodes and the drain electrodes;
forming the semiconductor film by applying the semiconductor coating liquid to the regions from which the lyophobic monolayer has been removed;
forming the passivation insulating film over the source electrodes, the drain electrodes and the semiconductor film;
forming the through holes by partially removing the passivation insulating film from above the source electrodes; and
forming the pixel electrodes on the passivation insulating film so as to be connected to the source electrodes through the intermediary of the through holes.

11. The process for producing a thin film transistor substrate according to claim 9, wherein the source electrodes and the drain electrodes are formed as reverse patterns in relation to the gate electrodes.

12. The process for producing a thin film transistor substrate according to claim 10, wherein each of the pixel electrodes is formed in one pixel unit constituted with one gate electrode constituted with one ring-shaped flat pattern, and the source electrode and the drain electrode, both corresponding to the gate electrode.

13. The process for producing a thin film transistor substrate according to claim 9, wherein the conductive ink is repelled from the lyophobic regions which is light shielded by the gate electrodes so as to gather together in the lyophilic regions.

14. The process for producing a thin film transistor substrate according to claim 13, wherein the substrate is vibrated while the conductive ink is being applied.
